(19) United States
(12) Patent Application Publication
(10) Pub. No.: US 2023/0058875 A1
(43) Pub. Date: Feb. 23, 2023

(54) WIDEBAND-ENABLED ELECTROACOUSTIC DEVICE

(71) Applicant: RF360 EUROPE GMBH, Munchen (DE)

(72) Inventors: Robert Felix BYWALEZ, Munich (DE); Willi AIGNER, Moosinning (DE); Ilya LUKASHOV, Munich (DE); Jouni Kristian KAUKOVUORI, Vantaa (FI)

(21) Appl. No.: 17/405,349

(22) Filed: Aug. 18, 2021

(51) Int. Cl. H03H 9/02; H01L 41/08

(52) U.S. Cl. CPC H03H 9/02015; H01L 41/08

(57) ABSTRACT

Certain aspects of the present disclosure can be implemented in an electroacoustic device. The electroacoustic device generally includes a substrate and one or more resonator structures disposed above the substrate. In some cases, each resonator structure of the one or more resonator structures includes a bulk acoustic resonator, an acoustic mirror disposed below the bulk acoustic resonator, and one or more porous material layers disposed below the acoustic mirror and above the substrate.

### BACKGROUND

### Field of the Disclosure

Aspects of the present disclosure relate to electronic devices, and more particularly, to an electroacoustic device.

### Description of Related Art

Electronic devices include computing devices such as desktop computers, notebook computers, tablet computers, smartphones, wearable devices like a smartwatch, Internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast, and so on. Wireless communication devices may transmit and/or receive radio frequency (RF) signals via any of various suitable radio access technologies (RATs) including, but not limited to, 5G New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., IEEE 802.11), and the like.

Wireless communication transceivers used in these electronic devices generally include multiple radio frequency (RF) filters for filtering a signal for a particular frequency or range of frequencies. Electroacoustic devices (e.g., “acoustic filters”) are used for filtering high frequency (e.g., generally greater than 500 MHz) signals in many applications. Using a piezoelectric material as a vibrating medium, acoustic resonators operate by transforming an electrical signal wave that is propagating along an electrical conductor into an acoustic wave that is propagating via the piezoelectric material. The acoustic wave propagates at a velocity having a magnitude that is significantly less than that of the propagation velocity of the electromagnetic wave. Generally, the magnitude of the propagation velocity of a wave is proportional to a size of a wavelength of the wave. Consequently, after conversion of an electrical signal into an acoustic signal, the wavelength of the acoustic signal wave is significantly smaller than the wavelength of the electrical signal wave. The resulting smaller wavelength of the acoustic signal enables filtering to be performed using a smaller filter device. This permits acoustic resonators to be used in electronic devices having size constraints, such as the electronic devices enumerated above (e.g., particularly including portable electronic devices such as smartphones).

As the number of frequency bands used in wireless communications increases and as the desired frequency bands of filters widen, the performance of acoustic filters increases in importance to reduce resistive losses, increase attenuation of out-of-band signals, and increase overall performance of electronic devices. Acoustic filters with improved performance are, therefore, sought after.

### SUMMARY

Certain aspects of the present disclosure can be implemented in an electroacoustic device. The electroacoustic device generally includes a substrate and one or more resonator structures disposed above the substrate. In some cases, each resonator structure of the one or more resonator structures includes a bulk acoustic resonator, an acoustic mirror disposed below the bulk acoustic resonator, and one or more porous material layers disposed below the acoustic mirror and above the substrate.

Certain aspects of the present disclosure can be implemented in a wireless device comprising the electroacoustic device described herein. The wireless device further includes an antenna, a transmit path, and a receive path, wherein the electroacoustic device is coupled between the antenna and at least one of the transmit path or the receive path.

Certain aspects of the present disclosure can be implemented in a method for signal processing. The method generally includes receiving a signal at an input of an electroacoustic device and processing the signal via the electroacoustic device. The electroacoustic device comprises a substrate and one or more resonator structures disposed above the substrate. In some cases, each resonator structure of the one or more resonator structures includes a bulk acoustic resonator, an acoustic mirror disposed below the bulk acoustic resonator, and one or more porous material layers disposed below the acoustic mirror and above the substrate.

Certain aspects of the present disclosure are directed to a method of fabricating an electroacoustic device. The method generally includes forming one or more resonator structures above a substrate. In some cases, each resonator structure of the one or more resonator structures comprises a bulk acoustic resonator, an acoustic mirror disposed below the bulk acoustic resonator, and one or more porous material layers disposed below the acoustic mirror and above the substrate.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the drawings. It is to be noted, however, that the appended drawings illustrate only certain typical aspects of this disclosure and are therefore not to be considered limiting of its scope, for the description may admit to other equally effective aspects.

FIG. 1A is a diagram conceptually illustrating an example electroacoustic device, in accordance with certain aspects of the present disclosure.

FIG. 1B is a diagram illustrating a cross-section of the example electroacoustic device of FIG. 1A, in accordance with certain aspects of the present disclosure.

FIG. 2 illustrates a cross-section of an example electroacoustic device implementing one or more porous material layers, in accordance with certain aspects of the present disclosure.

FIG. 3 illustrates a cross-section of an example electroacoustic device implementing one or more discontinuous porous material layers, in accordance with certain aspects of the present disclosure.

FIG. 4 is a flow diagram illustrating example operations for fabricating an electroacoustic device, in accordance with certain aspects of the present disclosure.

FIG. 5 is a flow diagram illustrating example operations for signal processing using an electroacoustic device, in accordance with certain aspects of the present disclosure.

FIG. 6 is a diagram of an example transceiver in which an electroacoustic device may be employed, in accordance with certain aspects of the present disclosure.

FIG. 7 is a diagram of a wireless communication network that includes a wireless communication device having a transceiver, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Aspects of the present disclosure provide an electroacoustic device having at least one porous material layer disposed below a resonator structure, such as an electroacoustic filter device. The porous material layer may reduce manufacturing complexity and cost of electroacoustic filters by providing a ready-to-use substrate that may be used to fabricate multiple electroacoustic filters targeting different passbands within a wide range of frequencies.

### Introduction to Electroacoustic Filter Devices

Electroacoustic devices, such as bulk acoustic wave (BAW) filters or resonators, are receiving great interest for radio frequency (RF) selectivity in mobile communication systems and other wireless applications. A BAW resonator (also referred to as a “bulk acoustic resonator”) is an electromechanical device that is composed of a piezoelectric material arranged between electrode structures, such as a bottom electrode and a top electrode. When an electric current is applied to the BAW resonator, charge may build up on the bottom electrode and generate an elastic or acoustic wave in the piezoelectric material that travels to, and is reflected by, the top electrode. Due to this reflective behavior, the acoustic waves within the piezoelectric material may “build on each other,” creating a standing wave that oscillates at a particular resonance frequency. The resonance frequency may be controlled by a thickness of the piezoelectric material and enables the BAW resonator to function as a filter or oscillator, for example. In the case of a filter, the resonant frequency of the BAW resonator may be associated with a range of frequencies in which signals are permitted to pass through the BAW resonator, known as a passband, while signals outside of this range of frequencies (e.g., in the stopband) are attenuated and effectively blocked by the BAW resonator.

Different types of BAW resonators may exist and are designed to reduce leakage from the piezoelectric material. One type of BAW resonator is referred to as a thin-film bulk acoustic resonator (FBAR). An FBAR may include piezoelectric material manufactured by thin-film methods sandwiched between two electrodes and acoustically isolated from a substrate material by an air gap disposed beneath the bottom electrode. A solidly mounted resonator (SMR) is another type of BAW resonator having a piezoelectric thin film sandwiched between two electrodes. However, unlike FBARs, SMRs include acoustic mirrors, known as Bragg mirrors or reflectors, disposed beneath the bottom electrode. A Bragg mirror may include alternating high and low acoustic impedance layers of quarter-wavelength thickness, designed to provide isolation from a substrate material by reflecting the acoustic wave generated by the piezoelectric layer back into the piezoelectric layer.

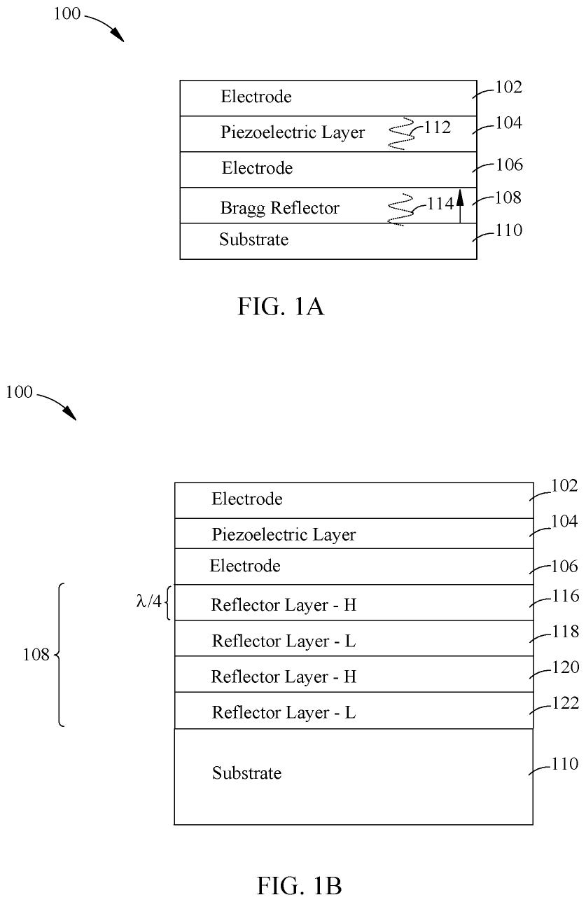

FIG. 1A illustrates a cross-section of an electroacoustic device 100. The electroacoustic device 100 may be configured as or be a portion of a BAW resonator, such as a BAW SMR. As shown, the electroacoustic device 100 includes a top electrode 102, a piezoelectric layer 104, a bottom electrode 106, a Bragg reflector 108, and a substrate 110.

As shown, the top electrode 102 is disposed above the piezoelectric layer 104. The top electrode 102 may include an electrically conductive material such as a metal or metal alloy including aluminum (Al), chromium (Cr), cobalt (Co), copper (Cu), gold (Au), molybdenum (Mo), platinum (Pt), ruthenium (Ru), tantalum (Ta), titanium (Ti), tungsten (W), a combination thereof (e.g., AlCu), or any other suitable material. In certain cases, the conductive material may include graphene or other electrically conductive, non-metallic materials. The piezoelectric layer 104 may include a piezoelectric material, such as aluminum nitride (AlN), aluminum scandium nitride (AlScN), zinc oxide (ZnO), a quartz crystal (such as lithium tantalate (LiTaO₃) or lithium niobite (LiNbO₃)), doped variants of these, or other suitable piezoelectric materials.

The bottom electrode 106 may include an electrically conductive material such as a metal or metal alloy, for example, as described herein with respect to the top electrode 102. In certain aspects, the bottom electrode 106 may have the same form, size, and/or structure as the top electrode 102. For example, the electrodes 102, 106 may both be electrode plates. In certain cases, the bottom electrode 106 may have a different form, size, and/or structure from the top electrode 102.

The Bragg reflector 108 may acoustically isolate the BAW resonator from the substrate 110 or at least reduce the acoustic coupling between the BAW resonator and the substrate 110. In general, the Bragg reflector 108 may include alternating layers of materials having low acoustic impedance and materials having high acoustic impedance, as further described herein with respect to FIG. 1B.

The substrate 110 may be disposed below the Bragg reflector 108, such that the substrate 110 is arranged under the top electrode 102 and the bottom electrode 106. The substrate 110 may serve as a carrier for the BAW resonator. In aspects, the substrate 110 may be formed from a semiconductor wafer such as a silicon (Si) wafer. The substrate 110 may comprise any of various other suitable materials, such as alumina (Al₂O₃), glass, or sapphire.

When an electrical signal (e.g., an AC voltage signal) is applied to the electrodes 102 and 106, the electrical signal is transformed into an acoustic wave 112 that propagates in the piezoelectric layer 104. That is, applying an electrical signal to the piezoelectric layer 104 between the electrodes 102 and 106 transduces the electrical signal to the acoustic wave 112 in the piezoelectric layer 104. At certain frequencies, a resonant and/or anti-resonant mechanical standing wave may be formed, thus enabling the filter functionality. As noted above, to avoid leakage into the substrate 110, the Bragg reflector 108 may be disposed below the bottom electrode 106. The Bragg reflector 108 may have high acoustic reflectivity and may reflect an acoustic wave 114 back towards the piezoelectric layer 104 and the top electrode 102. Reflecting the acoustic waves 114 may enhance the efficiency of the BAW resonator and acoustically decouple the substrate 110 from the BAW resonator. In many applications, the piezoelectric layer 104 has a particular crystal orientation such that when the top electrode 102 is arranged relative to the crystal orientation of the piezoelectric layer 104, the acoustic wave mainly propagates in a direction from the top electrode 102 to the bottom electrode 106.

FIG. 1B illustrates example reflector layers of the Bragg reflector 108 in the electroacoustic device 100, in accordance with certain aspects of the present disclosure. In this example, the Bragg reflector 108 includes a reflector layer 116, a reflector layer 118, a reflector layer 120, and a reflector layer 122. In certain cases, the Bragg reflector 108 may have any suitable number of reflector layers, such as fewer or more than four reflector layers as depicted in this example. The reflector layer 116 and reflector layer 120 may include a material having an acoustic impedance that is higher than the acoustic impedance of a material of the reflector layer 118 and reflector layer 122. For example, the reflector layer 118 and reflector layer 122 may include silicon dioxide (SiO₂) or aluminum nitride (AlN), whereas the reflector layer 116 and reflector layer 120 may include tungsten (W) or another suitable material with a higher acoustic impedance than silicon dioxide or aluminum nitride.

The reflector layers 116, 118, 120, 122 may have the same thickness (e.g., a quarter wavelength (λ/4) in thickness according to the operating frequency range of the electroacoustic device 100) or vary in thickness. While in this example, the reflector layers 116, 118, 120, 122 are depicted as having the same length, the reflector layers 116, 118, 120, 122 may vary in length (i.e., individual layers may have different lengths).

BAW resonators may be used for making radio frequency (RF) filters and duplexers and are more efficient at higher frequencies, such as 2 gigahertz (GHz) to 16 GHz. However, while BAW resonators are efficient at higher frequencies, it may be difficult to manufacture BAW resonators tuned to different frequency bands on the same wafer or in the same die. One reason why it is difficult to manufacture BAW resonators tuned to different frequency bands on the same wafer is because the respective resonant frequencies of the BAW resonators depend on the thicknesses of the piezoelectric layers within each BAW resonator. As such, differently tuned BAW resonators (e.g., tuned to different frequency bands) indicates different piezoelectric layer thicknesses. While these different piezoelectric layer thicknesses may be achieved using certain techniques, such as ion beam etching (IBE) and/or trimming, a bigger issue with manufacturing BAW resonators tuned to different frequency bands on the same wafer is that each differently tuned BAW resonator may demand a different Bragg mirror tuned to a respective BAW resonator, which may significantly complicate the manufacturing process. As such, manufacturing differently tuned BAW resonators on a single wafer is typically cost prohibitive. As a consequence, the BAW resonator manufacturing process conventionally involves manufacturing only similarly tuned BAW resonators on the same wafer, which may lead to wasted space on the wafer (and in a device having differently tuned BAW resonators fabricated on multiple different wafers).

Thus, aspects of the present disclosure provide techniques for reducing manufacturing complexity associated with manufacturing differently tuned BAW resonators on a same wafer. In some cases, such techniques may involve fabricating one or more porous material layers within a BAW resonator. In some cases, the one or more porous material layers may be disposed below an acoustic mirror (e.g., Bragg mirror) and above a substrate of the BAW resonator. The one or more porous material layers may function to expand an operating frequency range of the acoustic mirror, allowing the same acoustic mirror to be used for differently tuned BAW resonators on the same wafer. As a consequence, the manufacturing complexity associated with manufacturing differently tuned BAW resonators on the same wafer may be significantly reduced since the same acoustic mirror may be used for differently tuned BAW resonators.

### Example Wideband-Enabled Electroacoustic Device

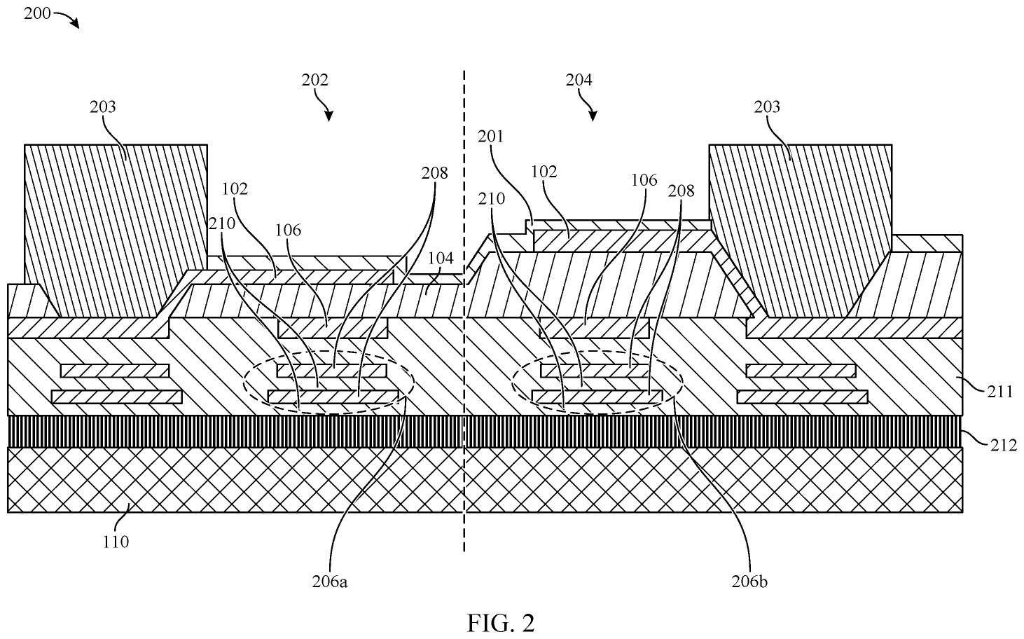

FIG. 2 illustrates a cross-section of an example electroacoustic device 200 implementing one or more porous material layers, in accordance with certain aspects of the present disclosure. In some cases, the electroacoustic device 200 includes a BAW SMR. As shown, the electroacoustic device 200 includes a substrate 110 and one or more resonator structures disposed above the substrate, such as a first acoustic filter 202 and a second acoustic filter 204. In some cases, the first acoustic filter 202 and the second acoustic filter 204 may be arranged and connected in series or in parallel with each other. In some cases, the substrate 110 may be formed from a semiconductor wafer such as a silicon (Si) wafer. In some cases, the substrate 110 may comprise any of various other suitable materials, such as alumina, glass, or sapphire.

As shown, the one or more resonator structures (e.g., the first acoustic filter 202 and the second acoustic filter 204) each include a bulk acoustic resonator composed of a top electrode 102, a piezoelectric layer 104 disposed below the top electrode 102, and a bottom electrode 106 disposed below the piezoelectric layer 104. In some cases, the top electrode 102, the piezoelectric layer 104, and the bottom electrode 106 may be composed of any suitable materials as discussed above with respect to FIG. 1A. Additionally, as shown, the electroacoustic device 200 includes interconnects 203 for providing electrical connection to the first acoustic filter 202 and to the second acoustic filter 204. Additionally, as shown, the electroacoustic device 200 may include a trimming layer 201 that is disposed above (e.g., on top of) the top electrodes 102 and other portions of the electroacoustic device 200. The trimming layer 201 may be composed of any suitable material, such as silicon nitride (Si₃N₄). In some case, the trimming layer 201 may be used to adjust a respective resonant frequency of the first acoustic filter 202 and the second acoustic filter 204.

In some cases, the first acoustic filter 202 and the second acoustic filter 204 may share the piezoelectric layer 104. Further, in some cases, the first acoustic filter 202 and the second acoustic filter 204 may be tuned to a same resonant frequency, while in other cases, the first and second acoustic filter may be tuned to different resonant frequencies. In some cases, ion beam etching (IBE) may be used to change a thickness of the piezoelectric layer 104 for tuning the one or more resonator structures (e.g., the first acoustic filter 202 and the second acoustic filter 204) to one or more suitable resonant frequencies. Additionally, selective removal of portions of the trimming layer 201 may also be used to tune the resonant frequency of the first acoustic filter 202 and/or the second acoustic filter 204.

When the first acoustic filter 202 and the second acoustic filter 204 are tuned to different resonant frequencies, a first thickness of the piezoelectric layer 104 in the first acoustic filter 202 may be different from a second thickness of the piezoelectric layer 104 in the second acoustic filter 204, as shown. For example, in some cases, a thickness of the piezoelectric layer 104 may vary between two different levels and is in a range between about 100 nm and 600 nm, depending on the targeted resonant frequency/passband for each of the acoustic filters 202, 204. In some cases, for example, when the first acoustic filter 202 is tuned to a resonant frequency between 4400 MHz and 5000 MHz (e.g., an n79 Fifth Generation (5G) frequency band) and the second acoustic filter 204 is tuned to a resonant frequency between 3300 MHz and 4200 MHz (e.g., an n77 5G frequency band), a difference in the thickness of the shared piezoelectric layer between the two different levels may be about 300 nm. In other words, the height difference between the portion of the shared piezoelectric layer 104 in the first acoustic filter 202 and the portion of the shared piezoelectric layer 104 in the second acoustic filter 204 may be about 300 nm in this case.

In some cases, depending upon the particular application, the top electrode 102 of the first acoustic filter 202 and the second acoustic filter 204 may also be shared. Regardless whether the top electrode 102 is shared between the first acoustic filter 202 and the second acoustic filter 204, a first thickness of the top electrode 102 of the first acoustic filter 202 may be different from a second thickness of the top electrode 102 of the second acoustic filter 204.

Further, as shown in FIG. 2, each resonator structure of the one or more resonator structures may include an acoustic mirror. For example, as shown, the first acoustic filter 202 may include a first acoustic mirror 206a, and the second acoustic filter 204 may include a second acoustic mirror 206b. The first acoustic mirror 206a and the second acoustic mirror 206b include one or more reflector layers that have a high acoustic reflectivity and are configured to reflect an acoustic wave back towards the piezoelectric layer 104. The one or more reflector layers include reflector layers 208 and reflector layers 210. In certain cases, the one or more reflector layers may have any suitable number of reflector layers, such as fewer or more than four reflector layers as depicted in the example shown in FIG. 2. The reflector layers 208 may be composed of a material having an acoustic impedance that is higher than the acoustic impedance of a material of the reflector layers 210. For example, the reflector layers 210 may include silicon dioxide (SiO₂) or aluminum nitride (AlN), whereas the reflector layers 208 may include tungsten (W), titanium (Ti), or other suitable materials with a higher acoustic impedance than silicon dioxide or aluminum nitride. In some cases, as shown in FIG. 2, the reflector layers 210 may be formed as part of a dielectric material layer 211 disposed between the substrate 110 and piezoelectric layer 104. As such, when forming the electroacoustic device 200, the dielectric material layer 211 (e.g., serving partially as the reflector layers 210) may be formed around the reflector layers 208.

Traditionally, a structure of the first acoustic mirror 206a of the first acoustic filter 202 may be different from a structure of the second acoustic mirror 206b of the second acoustic filter 204 because the first acoustic filter 202 and the second acoustic filter 204 are tuned to different resonant frequencies (e.g., based on respective thicknesses of the piezoelectric layer 104 within the first acoustic filter 202 and the second acoustic filter 204). For example, because the reflector layers of acoustic mirrors in traditional acoustic filters are generally a quarter of a wavelength (λ/4) in thickness of the operating frequency range or resonant frequency of the acoustic filter, thicknesses of the reflector layers 208, 210 of the first acoustic mirror 206a and the second acoustic mirror 206b would traditionally be individually adjusted to suit the resonant frequencies of the first acoustic filter 202 and second acoustic filter 204 (e.g., such that the first acoustic mirror 206a and second acoustic mirror 206 properly reflect acoustic waves back into the piezoelectric layer 104 of the first acoustic filter 202 and second acoustic filter 204, respectively). As such, the manufacturing complexity associated with manufacturing the first acoustic filter 202 and the second acoustic filter 204 on the same wafer would be significant.

However, to avoid such manufacturing complexity, the first acoustic filter 202 and the second acoustic filter 204 may include one or more porous material layers 212 disposed below the first and second acoustic mirrors 206a, 206b and above the substrate 110. As noted above, the one or more porous material layers 212 may function to expand an operating frequency of the first and second acoustic mirrors 206a, 206b to a wider band of frequencies, such that the first and second acoustic mirrors 206a, 206b may have the same structure while still functioning properly for the first acoustic filter 202 and second acoustic filter 204 that are tuned to different resonant frequencies. In other words, by including the one or more porous material layers 212, the same acoustic mirror may be used for acoustic filters tuned to different resonant frequencies, which significantly reduces manufacturing complexity associated with manufacturing differently tuned acoustic filters, such as the first acoustic filter 202 and second acoustic filter 204, on the same wafer.

At least one of the one or more porous material layers may have a porosity between about 60 and 90 percent. In some cases, the porosity of the at least one of the one or more porous material layers is between about 70 and 80 percent. Additionally, in some cases, at least one of the one or more porous material layers has a thickness between 50 nanometers (nm) and 500 nm. For example, at least one of the one or more porous material layers may have a thickness of about 200 nm. In some cases, at least one of the one or more porous material layers is composed of porous silicon (Si). Additionally or alternatively, at least one of the one or more porous material layers may be composed of porous silica (SiO₂).

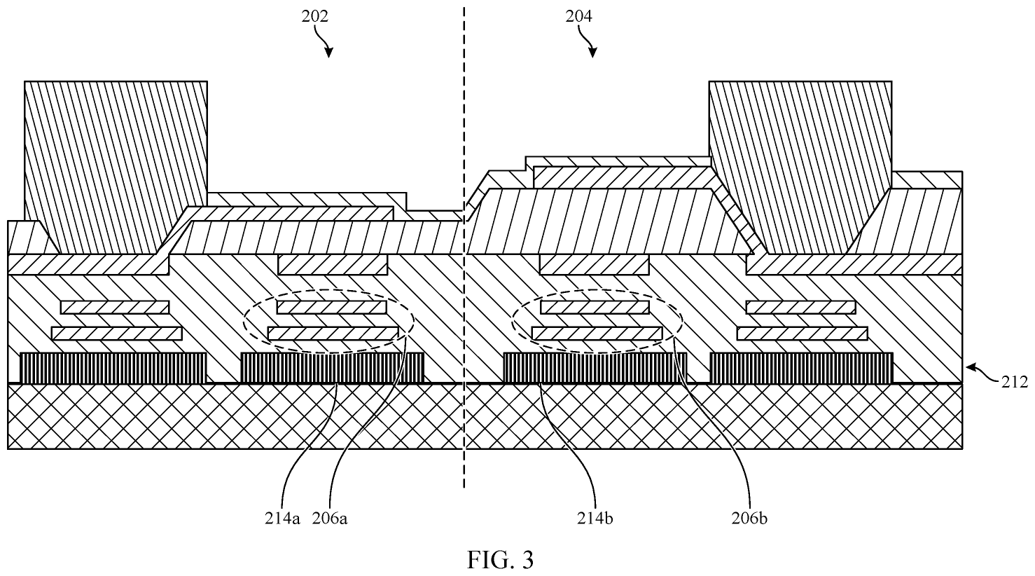

In some cases, as illustrated in FIG. 2, the one or more porous material layers 212 may comprise one continuous region disposed beneath the first acoustic filter 202 and the second acoustic filter 204. In other cases, such as illustrated in FIG. 3, one or more porous material layers 212 may include a plurality of disjointed porous material regions 214, each formed beneath a respective acoustic mirror, such as the first acoustic mirror 206a of the first acoustic filter 202 and the second acoustic mirror 206b of the second acoustic filter 204. Accordingly, as illustrated in FIG. 3, the first acoustic filter 202 includes a first porous material region 214a, and the second acoustic filter 204 includes a second porous material region 214b. In some cases, the first porous material region 214a has a similar porosity as the second porous material region 214b. In other cases, the first porous material region 214a has a substantially different porosity than the second porous material region 214b. Further, in some cases, the first porous material region 214a may be composed of the same type of material or the same combination of types of materials as the second porous material region 214b. In other cases, the first porous material region 214a may be composed of a material or combination of materials that is different from the second porous material region 214b.

### Example Operations for Fabricating a Wideband-Enabled Electroacoustic Device

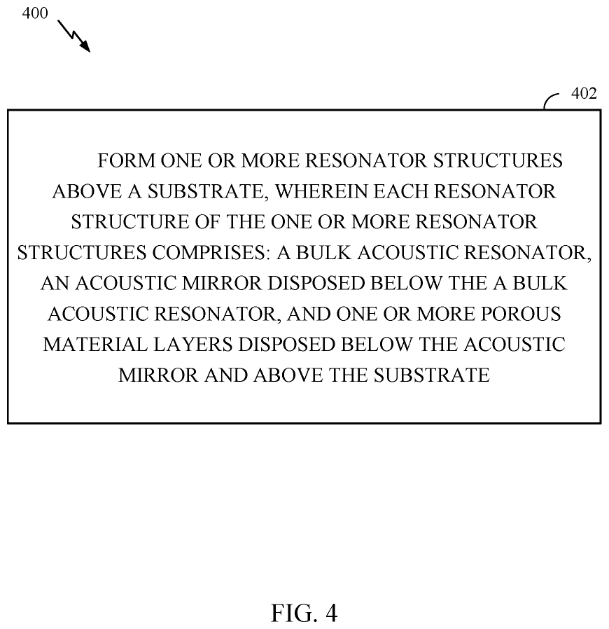

FIG. 4 is a flow diagram illustrating example operations 400 for fabricating an electroacoustic device including one or more porous material layers, in accordance with certain aspects of the present disclosure. The operations 400 may be performed, for example, by a semiconductor processing facility.

Operations 400 may begin, at block 402, with forming one or more resonator structures disposed above a substrate such that each resonator structure of the one or more resonator structures comprises a bulk acoustic resonator, an acoustic mirror disposed below the bulk acoustic resonator, and one or more porous material layers disposed below the acoustic mirror and above the substrate. The bulk acoustic resonator may include a top electrode, a piezoelectric layer disposed below the top electrode, and a bottom electrode disposed below the piezoelectric layer.

In some cases, forming the one or more resonator structures in block 402 includes forming the one or more porous material layers above the substrate, forming the acoustic mirror above the one or more porous material layers, forming the bottom electrode above the acoustic mirror, forming the piezoelectric layer above the bottom electrode, and forming the top electrode above the piezoelectric layer.

In some cases, forming the one or more resonator structures in block 402 comprises forming a first acoustic filter and forming a second acoustic filter. In some cases, the first acoustic filter and the second acoustic filter share the piezoelectric layer. In some cases, a structure of the acoustic mirror of the first acoustic filter is the same as a structure of the acoustic mirror of the second acoustic filter.

In some cases, at least one of forming the first acoustic filter or forming the second acoustic filter comprises performing ion beam etching (IBE) on a respective portion of the shared piezoelectric layer.

In some cases, based on the IBE performed on the shared piezoelectric layer, a first thickness of the shared piezoelectric layer in the first acoustic filter is different from a second thickness of the shared piezoelectric layer in the second acoustic filter.

In some cases, based on the IBE performed on the shared piezoelectric layer, a thickness of the shared piezoelectric layer varies between two different levels and is in a range between about 100 nm and 600 nm. Further, in some cases, a difference in the thickness of the shared piezoelectric layer between the two different levels is about 300 nm.

In some cases, a first thickness of the top electrode of the first acoustic filter is different from a second thickness of the top electrode of the second acoustic filter.

In some cases, forming the first acoustic filter comprises forming a first porous material layer of the one or more porous material layers. Additionally, in some cases, forming the second acoustic filter comprises forming a second porous material layer of the one or more porous material layers. In some cases, the first porous material layer has a substantially different porosity than the second porous material layer. In some cases, the second porous material layer is composed of a different material than the first porous material layer.

In some cases, at least one of the one or more porous material layers has a porosity between about 60 and 90 percent. In some cases, the porosity of the at least one of the one or more porous material layers is between about 70 and 80 percent.

In some cases, at least one of the one or more porous material layers has a thickness between 50 nanometers (nm) and 500 nm.

In some cases, at least one of the one or more porous material layers is composed of porous silicon (Si).

In some cases, at least one of the one or more porous material layers is composed of porous silica (SiO₂).

In some cases, at least one of the one or more resonator structures comprises a solidly mounted resonator (SMR).

In some cases, each resonator structure of the one or more resonator structures further comprises a trimming layer disposed above the bulk acoustic resonator. In some cases, the trimming layer is composed of silicon nitride (Si₃N₄).

### Example Operations for Processing a Signal Using a Wideband-Enabled Electroacoustic Device

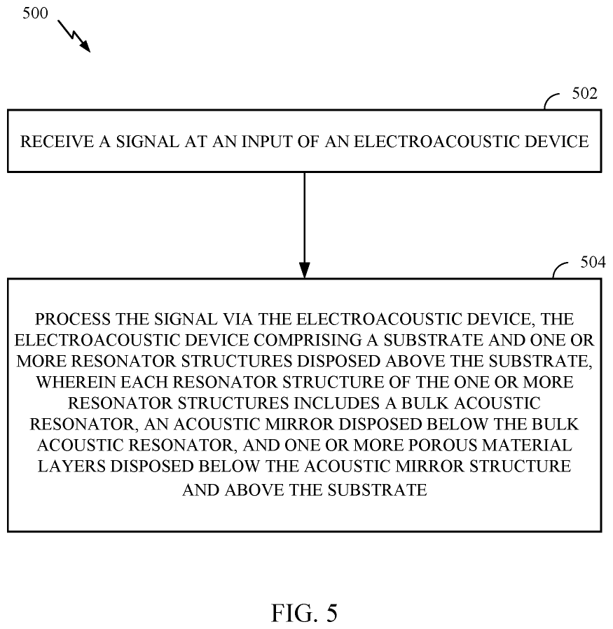

FIG. 5 is a flow diagram illustrating example operations 500 for signal processing, in accordance with certain aspects of the present disclosure. The operations 500 may be performed, for example, by an electroacoustic device such as the electroacoustic device 200.

The operations 500 may begin, at block 502, by receiving a signal at a terminal (e.g., an electrode) of an electroacoustic device, and at block 504, processing the signal via the electroacoustic device. The electroacoustic device may include a substrate (e.g., substrate 110 of FIG. 2) and one or more resonator structures disposed above the substrate (e.g., first acoustic filter 202 and second acoustic filter 204 of FIG. 2). Each of the one or more resonator structures may include a bulk acoustic resonator, an acoustic mirror (e.g., first and second acoustic mirrors 206a, 206b) disposed below the bulk acoustic resonator, and one or more porous material layers (e.g., the one or more porous material layers 212 of FIG. 2 and/or the first porous material region 214a and the second porous material region 214b of FIG. 3) disposed below the acoustic mirror and above the substrate. The bulk acoustic resonator may be composed of a top electrode (e.g., top electrode 102 of FIG. 2), a piezoelectric layer (e.g., piezoelectric layer 104 of FIG. 2) disposed below the top electrode, and a bottom electrode (e.g., bottom electrode 106 of FIG. 2) disposed below the piezoelectric layer.

In some aspects, the terminal of the electroacoustic device at which the signal is received may be the bottom electrode layer. In some cases, the terminal of the electroacoustic device at which the signal is received may be the top electrode layer.

In some cases, the one or more resonator structures comprise a first acoustic filter and a second acoustic filter and wherein the first acoustic filter and the second acoustic filter share the piezoelectric layer.

In some cases, a first thickness of the shared piezoelectric layer in the first acoustic filter is different from a second thickness of the shared piezoelectric layer in the second acoustic filter.

In some cases, a thickness of the shared piezoelectric layer varies between two different levels and is in a range between about 100 nm and 600 nm.

In some cases, a difference in the thickness of the shared piezoelectric layer between the two different levels is about 300 nm.

In some cases, a first thickness of the top electrode of the first acoustic filter is different from a second thickness of the top electrode of the second acoustic filter.

In some cases, the first acoustic filter comprises a first porous material layer in the one or more porous material layers. In some cases, the second acoustic filter comprises a second porous material layer in the one or more porous material layers. Additionally, in some cases, the first porous material layer has a substantially different porosity than the second porous material layer.

In some cases, at least one of the one or more porous material layers has a porosity between about 60 and 90 percent.

In some cases, the porosity of the at least one of the one or more porous material layers is between about 70 and 80 percent.

In some cases, at least one of the one or more porous material layers has a thickness between 50 nanometers (nm) and 500 nm.

In some cases, at least one of the one or more porous material layers is composed of porous silicon (Si).

In some cases, at least one of the one or more porous material layers is composed of porous silica (SiO₂).

In some cases, the one or more porous material layers comprise a first porous material layer and a second porous material layer, the second porous material layer being composed of a different material than the first porous material layer.

In some cases, at least one of the one or more resonator structures comprises a solidly mounted resonator (SMR).

In some cases, the one or more resonator structures comprise a first acoustic filter and a second acoustic filter and wherein a structure of the acoustic mirror of the first acoustic filter is the same as a structure of the acoustic mirror of the second acoustic filter.

In some cases, each resonator structure of the one or more resonator structures further comprises a trimming layer disposed above the bulk acoustic resonator. In some cases, the trimming layer is composed of silicon nitride (Si₃N₄).

### Example Use Cases of an Electroacoustic Device

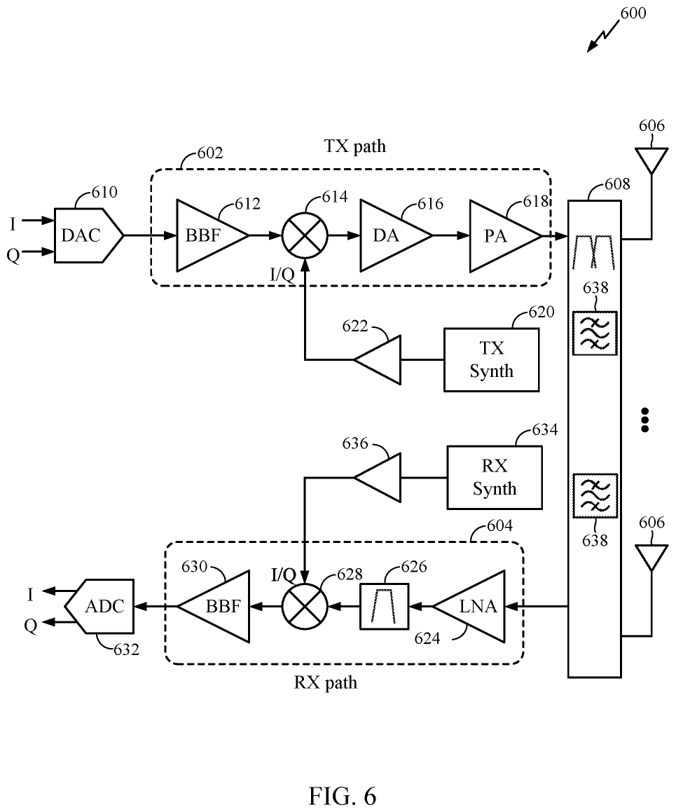

FIG. 6 is a block diagram of an example RF transceiver 600, in accordance with certain aspects of the present disclosure. In certain aspects, the electroacoustic device described herein may be employed in various circuits (such as an RF transceiver), for example, to serve as an electroacoustic filter or duplexer. The RF transceiver 600 may include at least one transmit (TX) path 602 (also known as a transmit chain) for transmitting signals via one or more antennas 606 and at least one receive (RX) path 604 (also known as a receive chain) for receiving signals via the antennas 606. In some cases, when implemented in certain devices, such as a Global Positioning System (GPS) receiver device, the RF transceiver 600 may include only RX paths and not include any TX paths. In such cases, the RF transceiver 600 may be considered an RF receiver device. When the TX path 602 and the RX path 604 share an antenna 606, the paths may be connected with the antenna via an interface 608, which may include any of various suitable RF devices, such as one or more electroacoustic filters 638 (e.g., the first acoustic filter 202 and/or the second acoustic filter 204), a duplexer, a diplexer, a multiplexer, and the like. In some cases, one or more electroacoustic filters 638, such as the first acoustic filter 202 and/or the second acoustic filter 204, may be used to form the duplexer, diplexer, and/or multiplexer.

Receiving in-phase (I) or quadrature (Q) baseband analog signals from a digital-to-analog converter (DAC) 610, the TX path 602 may include a baseband filter (BBF) 612, a mixer 614, a driver amplifier (DA) 616, and a power amplifier (PA) 618. In certain aspects, the BBF 612, the mixer 614, and the DA 616 may be included in a semiconductor device such as a radio frequency integrated circuit (RFIC), whereas the PA 618 may be external to this semiconductor device.

The BBF 612 filters the baseband signals received from the DAC 610, and the mixer 614 mixes the filtered baseband signals with a transmit local oscillator (LO) signal to convert the baseband signal of interest to a different frequency (e.g., upconvert from baseband to a radio frequency). This frequency conversion process produces the sum and difference frequencies between the LO frequency and the frequencies of the baseband signal of interest. The sum and difference frequencies are referred to as the beat frequencies. The beat frequencies are typically in the RF range, such that the signals output by the mixer 614 are typically RF signals, which may be amplified by the DA 616 and/or by the PA 618 before transmission by the antenna 606. In certain cases, the BBF 612 may be implemented using an electroacoustic filter with a BAW resonator (e.g., the electroacoustic device 200).

The RX path 604 may include a low noise amplifier (LNA) 624, a filter 626, a mixer 628, and a baseband filter (BBF) 630. In some implementations, the filter 626 may be implemented as part of the LNA 624. The LNA 624, the filter 626, the mixer 628, and the BBF 630 may be included in a RFIC, which may or may not be the same RFIC that includes the TX path components. RF signals received via the antenna 606 may be amplified by the LNA 624 and filtered by the filter 626, and the mixer 628 mixes the amplified RF signals with a receive local oscillator (LO) signal to convert the RF signal of interest to a different baseband frequency (e.g., downconvert). The baseband signals output by the mixer 628 may be filtered by the BBF 630 before being converted by an analog-to-digital converter (ADC) 632 to digital I or Q signals for digital signal processing. In certain cases, the filter 626 and/or BBF 630 may be implemented using an electroacoustic filter with a BAW resonator (e.g., the electroacoustic device 200).

While it is typically desirable for the output of an LO to remain stable in frequency, tuning to different frequencies indicates using a variable-frequency oscillator, which may involve compromises between stability and tunability. Some systems may employ frequency synthesizers with a voltage-controlled oscillator (VCO) to generate a stable, tunable LO with a particular tuning range. Thus, the transmit LO may be produced by a TX frequency synthesizer 620, which may be buffered or amplified by amplifier 622 before being mixed with the baseband signals in the mixer 614. Similarly, the receive LO may be produced by an RX frequency synthesizer 634, which may be buffered or amplified by amplifier 636 before being mixed with the RF signals in the mixer 628.

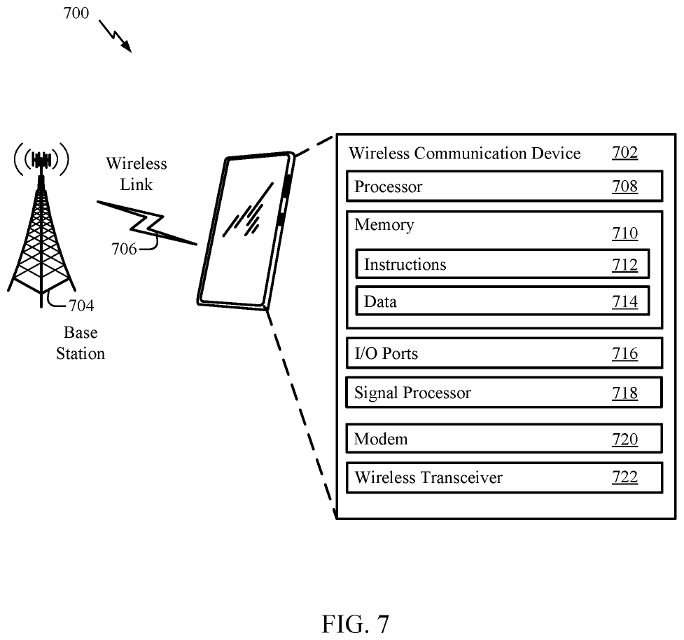

FIG. 7 is a diagram of an environment 700 that includes a wireless communication device 702, which has a wireless transceiver 722 such as the RF transceiver 600 of FIG. 6. In the environment 700, the wireless communication device 702 communicates with a base station 704 through a wireless link 706. As shown, the wireless communication device 702 is depicted as a smartphone. However, the wireless communication device 702 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, and so forth.

The base station 704 communicates with the wireless communication device 702 via the wireless link 706, which may be implemented as any suitable type of wireless link. Although depicted as a base station tower of a cellular radio network, the base station 704 may represent or be implemented as another device, such as a satellite, terrestrial broadcast tower, access point, peer-to-peer device, mesh network node, fiber optic line, another electronic device generally as described above, and so forth. Hence, the wireless communication device 702 may communicate with the base station 704 or another device via a wired connection, a wireless connection, or a combination thereof. The wireless link 706 can include a downlink of data or control information communicated from the base station 704 to the wireless communication device 702 and an uplink of other data or control information communicated from the wireless communication device 702 to the base station 704. The wireless link 706 may be implemented using any suitable communication protocol or standard, such as 3rd Generation Partnership Project Long-Term Evolution (3GPP LTE), 3GPP New Radio Fifth Generation (NR 5G), IEEE 802.11 (WiFi), IEEE 802.16 (WiMAX), Bluetooth™, and so forth.

The wireless communication device 702 includes a processor 708 and a memory 710. The memory 710 may be or form a portion of a computer-readable storage medium. The processor 708 may include any type of processor, such as an application processor or a multi-core processor, that is configured to execute processor-executable instructions (e.g., code) stored by the memory 710. The memory 710 may include any suitable type of data storage media, such as volatile memory (e.g., random access memory (RAM)), non-volatile memory (e.g., flash memory), optical media, magnetic media (e.g., disk or tape), and so forth. In the context of this disclosure, the memory 710 is implemented to store instructions 712, data 714, and other information of the wireless communication device 702, and thus when configured as or part of a computer-readable storage medium, the memory 710 does not include transitory propagating signals or carrier waves. That is, the memory 710 may include non-transitory computer-readable media (e.g., tangible media).

The wireless communication device 702 may also include input/output (I/O) ports 716. The I/O ports 716 enable data exchanges or interaction with other devices, networks, or users or between components of the device.

The wireless communication device 702 may further include a signal processor 718 (e.g., such as a digital signal processor (DSP)). The signal processor 718 may function similar to the processor 708 and may be capable of executing instructions and/or processing information in conjunction with the memory 710.

For communication purposes, the wireless communication device 702 also includes a modem 720, a wireless transceiver 722, and an antenna (not shown). The wireless transceiver 722 provides connectivity to respective networks and other wireless communication devices connected therewith using radio-frequency (RF) wireless signals and may include the RF transceiver 600 of FIG. 6. The wireless transceiver 722 may facilitate communication over any suitable type of wireless network, such as a wireless local area network (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

### EXAMPLE CLAUSES

Clause 1: An electroacoustic device, comprising: a substrate and one or more resonator structures disposed above the substrate, wherein each resonator structure of the one or more resonator structures comprises: a bulk acoustic resonator, an acoustic mirror disposed below the bulk acoustic resonator, and one or more porous material layers disposed below the acoustic mirror and above the substrate.

Clause 2: The electroacoustic device of Clause 2, wherein the bulk acoustic resonator comprises: a top electrode; a piezoelectric layer disposed below the top electrode; and a bottom electrode disposed below the piezoelectric layer.

Clause 3: The electroacoustic device of Clause 2, wherein the one or more resonator structures comprise a first acoustic filter and a second acoustic filter and wherein the first acoustic filter and the second acoustic filter share the piezoelectric layer.

Clause 4: The electroacoustic device of Clause 3, wherein a first thickness of the shared piezoelectric layer in the first acoustic filter is different from a second thickness of the shared piezoelectric layer in the second acoustic filter.

Clause 5: The electroacoustic device of any of Clauses 3-4, wherein a thickness of the shared piezoelectric layer varies between two different levels and is in a range between about 100 nm and 600 nm.

Clause 6: The electroacoustic device of Clause 5, wherein a difference in the thickness of the shared piezoelectric layer between the two different levels is about 300 nm.

Clause 7: The electroacoustic device of any of Clauses 3-6, wherein a first thickness of the top electrode of the first acoustic filter is different from a second thickness of the top electrode of the second acoustic filter.

Clause 8: The electroacoustic device of any of Clauses 3-7, wherein: the first acoustic filter comprises a first porous material layer in the one or more porous material layers, the second acoustic filter comprises a second porous material layer in the one or more porous material layers, and the first porous material layer has a different porosity than the second porous material layer.

Clause 9: The electroacoustic device of any of Clauses 1-8, wherein at least one of the one or more porous material layers has a porosity between about 60 and 90 percent.

Clause 10: The electroacoustic device of Clause 9, wherein the porosity of the at least one of the one or more porous material layers is between about 70 and 80 percent.

Clause 11: The electroacoustic device of any of Clauses 1-10, wherein at least one of the one or more porous material layers has a thickness between 50 nm and 500 nm.

Clause 12: The electroacoustic device of any of Clauses 1-11, wherein at least one of the one or more porous material layers is composed of porous silicon (Si) or porous silica (SiO₂).

Clause 13: The electroacoustic device of any of Clauses 1-12, wherein the one or more porous material layers comprise a first porous material layer and a second porous material layer, the second porous material layer being composed of a different material than the first porous material layer.

Clause 14: The electroacoustic device of any of Clauses 1-13, wherein at least one of the one or more resonator structures comprises a solidly mounted resonator (SMR).

Clause 15: The electroacoustic device of any of Clauses 1-14, wherein the one or more resonator structures comprise a first acoustic filter and a second acoustic filter and wherein a structure of the acoustic mirror of the first acoustic filter is the same as a structure of the acoustic mirror of the second acoustic filter.

Clause 16: The electroacoustic device of any of Clauses 1-15, wherein each resonator structure of the one or more resonator structures further comprises a trimming layer disposed above the bulk acoustic resonator, and wherein the trimming layer is composed of silicon nitride (Si₃N₄).

Clause 17: A wireless device comprising the electroacoustic device of any of Clauses 1-16, the wireless device further comprising: an antenna; a transmit path; and a receive path, wherein the electroacoustic device is coupled between the antenna and at least one of the transmit path or the receive path.

Clause 18: A method for signal processing, comprising receiving a signal at an input of an electroacoustic device, and processing the signal via the electroacoustic device, wherein the electroacoustic device comprises: a substrate and one or more resonator structures disposed above the substrate, wherein each resonator structure of the one or more resonator structures comprises: a bulk acoustic resonator, an acoustic mirror disposed below the bulk acoustic resonator; and one or more porous material layers disposed below the acoustic mirror and above the substrate.

Clause 19: The method of Clause 18, wherein the bulk acoustic resonator comprises: a top electrode; a piezoelectric layer disposed below the top electrode; and a bottom electrode disposed below the piezoelectric layer;

Clause 20: The method of Clause 19, wherein the one or more resonator structures comprise a first acoustic filter and a second acoustic filter and wherein the first acoustic filter and the second acoustic filter share the piezoelectric layer.

Clause 21: The method of Clause 20, wherein a first thickness of the shared piezoelectric layer in the first acoustic filter is different from a second thickness of the shared piezoelectric layer in the second acoustic filter.

Clause 22: The method of any of Clauses 20-21, wherein a thickness of the shared piezoelectric layer varies between two different levels and is in a range between about 100 nm and 600 nm.

Clause 23: The method of Clause 22, wherein a difference in the thickness of the shared piezoelectric layer between the two different levels is about 300 nm.

Clause 24: The method of any of Clauses 20-23, wherein a first thickness of the top electrode of the first acoustic filter is different from a second thickness of the top electrode of the second acoustic filter.

Clause 25: The method of any of Clauses 20-24, wherein: the first acoustic filter comprises a first porous material layer in the one or more porous material layers, the second acoustic filter comprises a second porous material layer in the one or more porous material layers, and the first porous material layer has a different porosity than the second porous material layer.

Clause 26: The method of any of Clauses 18-25, wherein at least one of the one or more porous material layers has a porosity between about 60 and 90 percent.

Clause 27: The method of Clause 26, wherein the porosity of the at least one of the one or more porous material layers is between about 70 and 80 percent.

Clause 28: The method of any of Clauses 18-27, wherein at least one of the one or more porous material layers has a thickness between 50 nm and 500 nm.

Clause 29: The method of any of Clauses 18-28, wherein at least one of the one or more porous material layers is composed of porous silicon (Si) or porous silica (SiO₂).

Clause 30: The method of any of Clauses 18-29, wherein the one or more porous material layers comprise a first porous material layer and a second porous material layer, the second porous material layer being composed of a different material than the first porous material layer.

Clause 31: The method of any of Clauses 18-30, wherein at least one of the one or more resonator structures comprises a solidly mounted resonator (SMR).

Clause 32: The method of any of Clauses 18-31, wherein the one or more resonator structures comprise a first acoustic filter and a second acoustic filter and

wherein a structure of the acoustic mirror of the first acoustic filter is the same as a structure of the acoustic mirror of the second acoustic filter.

Clause 33: The method of any of Clauses 18-32, wherein each resonator structure of the one or more resonator structures further comprises a trimming layer disposed above the bulk acoustic resonator, and wherein the trimming layer is composed of silicon nitride (Si₃N₄).

Clause 34: A method of fabricating an electroacoustic device, comprising forming one or more resonator structures above a substrate, wherein each resonator structure of the one or more resonator structures comprises: a bulk acoustic resonator, an acoustic mirror disposed below the bulk acoustic resonator, and one or more porous material layers disposed below the acoustic mirror and above the substrate.

Clause 35: The method of Clause 34, wherein the bulk acoustic resonator comprises a top electrode; a piezoelectric layer disposed below the top electrode; and a bottom electrode disposed below the piezoelectric layer.

Clause 36: The method of Clause 35, wherein forming the one or more resonator structures comprises forming a first acoustic filter and forming a second acoustic filter.

Clause 37: The method of Clause 36, wherein the first acoustic filter and the second acoustic filter share the piezoelectric layer.

Clause 38: The method of any of Clauses 36-37, wherein at least one of forming the first acoustic filter or forming the second acoustic filter comprises performing ion beam etching (IBE) on a respective portion of the shared piezoelectric layer.

Clause 39: The method of Clause 38, wherein, based on the IBE performed on the shared piezoelectric layer, a first thickness of the shared piezoelectric layer in the first acoustic filter is different from a second thickness of the shared piezoelectric layer in the second acoustic filter.

Clause 40: The method of any of Clauses 38-39, wherein, based on the IBE performed on the shared piezoelectric layer, a thickness of the shared piezoelectric layer varies between two different levels and is in a range between about 100 nm and 600 nm.

Clause 41: The method of Clause 40, wherein a difference in the thickness of the shared piezoelectric layer between the two different levels is about 300 nm.

Clause 42: The method of any of Clauses 36-41, wherein a first thickness of the top electrode of the first acoustic filter is different from a second thickness of the top electrode of the second acoustic filter.

Clause 43: The method of any of Clauses 36-42, wherein a structure of the acoustic mirror of the first acoustic filter is the same as a structure of the acoustic mirror of the second acoustic filter.

Clause 44: The method of any of Clauses 36-43, wherein: forming the first acoustic filter comprises forming a first porous material layer of the one or more porous material layers, and forming the second acoustic filter comprises forming a second porous material layer of the one or more porous material layers.

Clause 45: The method of Clause 44, wherein the first porous material layer has a different porosity than the second porous material layer.

Clause 46: The method of any of Clauses 44-45, wherein the second porous material layer is composed of a different material than the first porous material layer.

Clause 47: The method of any of Clauses 34-46, wherein at least one of the one or more porous material layers has a porosity between about 60 and 90 percent.

Clause 48: The method of Clause 47, wherein the porosity of the at least one of the one or more porous material layers is between about 70 and 80 percent.

Clause 49: The method of any of Clauses 34-48, wherein at least one of the one or more porous material layers has a thickness between 50 nm and 500 nm.

Clause 50: The method of any of Clauses 34-49, wherein at least one of the one or more porous material layers is composed of porous silicon (Si) or porous silica (SiO₂).

Clause 51: The method of any of Clauses 34-50, wherein at least one of the one or more resonator structures comprises a solidly mounted resonator (SMR).

Clause 52: The method of any of Clauses 34-51, wherein each resonator structure of the one or more resonator structures further comprises a trimming layer disposed above the bulk acoustic resonator, and wherein the trimming layer is composed of silicon nitride (Si₃N₄).

### Additional Considerations

The various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components.

The following description provides examples of an electroacoustic device for various filtering applications, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

The various operations of methods described above may be performed by any suitable means capable of performing the corresponding functions. The means may include various hardware components. Generally, where there are operations illustrated in figures, those operations may have corresponding counterpart means-plus-function components with similar numbering.

It is to be understood that the claims are not limited to the precise configuration and components illustrated above. Various modifications, changes, and variations may be made in the arrangement, operation, and details of the methods and apparatus described above without departing from the scope of the claims.

1. An electroacoustic device comprising:
a substrate; and
one or more resonator structures disposed above the substrate, wherein each resonator structure of the one or more resonator structures comprises:
a bulk acoustic resonator;
an acoustic mirror disposed below the bulk acoustic resonator; and
one or more porous material layers disposed below the acoustic mirror and above the substrate.

2. The electroacoustic device of claim 1, wherein the bulk acoustic resonator comprises:
a top electrode;
a piezoelectric layer disposed below the top electrode; and
a bottom electrode disposed below the piezoelectric layer.

3. The electroacoustic device of claim 2, wherein the one or more resonator structures comprise a first acoustic filter and a second acoustic filter and wherein the first acoustic filter and the second acoustic filter share the piezoelectric layer.

4. The electroacoustic device of claim 3, wherein a first thickness of the shared piezoelectric layer in the first acoustic filter is different from a second thickness of the shared piezoelectric layer in the second acoustic filter.

5. The electroacoustic device of claim 3, wherein a thickness of the shared piezoelectric layer varies between two different levels and is in a range between about 100 nm and 600 nm.

6. The electroacoustic device of claim 5, wherein a difference in the thickness of the shared piezoelectric layer between the two different levels is about 300 nm.

7. The electroacoustic device of claim 3, wherein a first thickness of the top electrode of the first acoustic filter is different from a second thickness of the top electrode of the second acoustic filter.

8. The electroacoustic device of claim 3, wherein:
the first acoustic filter comprises a first porous material layer in the one or more porous material layers,
the second acoustic filter comprises a second porous material layer in the one or more porous material layers, and
the first porous material layer has a different porosity than the second porous material layer.

9. The electroacoustic device of claim 1, wherein at least one of the one or more porous material layers has a porosity between about 60 and 90 percent.

10. The electroacoustic device of claim 9, wherein the porosity of the at least one of the one or more porous material layers is between about 70 and 80 percent.

11. The electroacoustic device of claim 1, wherein at least one of the one or more porous material layers has a thickness between 50 nm and 500 nm.

12. The electroacoustic device of claim 1, wherein at least one of the one or more porous material layers is composed of porous silicon (Si) or porous silica (SiO₂).

13. The electroacoustic device of claim 1, wherein the one or more porous material layers comprise a first porous material layer and a second porous material layer, the second porous material layer being composed of a different material than the first porous material layer.

14. The electroacoustic device of claim 1, wherein at least one of the one or more resonator structures comprises a solidly mounted resonator (SMR).

15. The electroacoustic device of claim 1, wherein the one or more resonator structures comprise a first acoustic filter and a second acoustic filter and wherein a structure of the acoustic mirror of the first acoustic filter is the same as a structure of the acoustic mirror of the second acoustic filter.

16. The electroacoustic device of claim 1, wherein each resonator structure of the one or more resonator structures further comprises a trimming layer disposed above the bulk acoustic resonator, and wherein the trimming layer is composed of silicon nitride (Si₃N₄).

17. A wireless device comprising the electroacoustic device of claim 1, the wireless device further comprising:
an antenna;
a transmit path; and
a receive path, wherein the electroacoustic device is coupled between the antenna and at least one of the transmit path or the receive path.

18. A method of fabricating an electroacoustic device, comprising:
forming one or more resonator structures above a substrate, wherein each resonator structure of the one or more resonator structures comprises:
a bulk acoustic resonator;
an acoustic mirror disposed below the bulk acoustic resonator; and
one or more porous material layers disposed below the acoustic mirror and above the substrate.

19. The method of claim 18, wherein:
the bulk acoustic resonator comprises:
a top electrode,
a piezoelectric layer disposed below the top electrode, and
a bottom electrode disposed below the piezoelectric layer;
forming the one or more resonator structures comprises forming a first acoustic filter and forming a second acoustic filter; and
the first acoustic filter and the second acoustic filter share the piezoelectric layer.

20. The method of claim 19, wherein at least one of forming the first acoustic filter or forming the second acoustic filter comprises performing ion beam etching (IBE) on a respective portion of the shared piezoelectric layer.

21. The method of claim 20, wherein, based on the IBE performed on the shared piezoelectric layer, a first thickness of the shared piezoelectric layer in the first acoustic filter is different from a second thickness of the shared piezoelectric layer in the second acoustic filter.

22. The method of claim 20, wherein, based on the IBE performed on the shared piezoelectric layer, a thickness of the shared piezoelectric layer varies between two different levels and is in a range between about 100 nm and 600 nm.

23. The method of claim 19, wherein:
forming the first acoustic filter comprises forming a first porous material layer of the one or more porous material layers, and
forming the second acoustic filter comprises forming a second porous material layer of the one or more porous material layers.

24. The method of claim 19, wherein a structure of the acoustic mirror of the first acoustic filter is the same as a structure of the acoustic mirror of the second acoustic filter.

25. The method of claim 18, wherein at least one of the one or more porous material layers is composed of porous silicon (Si) or porous silica (SiO₂).

26. The method of claim 18, wherein at least one of the one or more porous material layers has a porosity between about 60 and 90 percent.

27. A method for signal processing, comprising:
receiving a signal at an input of an electroacoustic device; and
processing the signal via the electroacoustic device, wherein the electroacoustic device comprises:
a substrate; and
one or more resonator structures disposed above the substrate, wherein each resonator structure of the one or more resonator structures comprises:
a bulk acoustic resonator;
an acoustic mirror disposed below the bulk acoustic resonator; and
one or more porous material layers disposed below the acoustic mirror and above the substrate.

28. The method of claim 27, wherein:
the bulk acoustic resonator comprises:
a top electrode,
a piezoelectric layer disposed below the top electrode, and
a bottom electrode disposed below the piezoelectric layer;
the one or more resonator structures comprise a first acoustic filter and a second acoustic filter;
the first acoustic filter and the second acoustic filter share the piezoelectric layer; and
a first thickness of the shared piezoelectric layer in the first acoustic filter is different from a second thickness of the shared piezoelectric layer in the second acoustic filter.

29. The method of claim 28, wherein:
a structure of the acoustic mirror of the first acoustic filter is the same as a structure of the acoustic mirror of the second acoustic filter, and
a thickness of the shared piezoelectric layer varies between two different levels and is in a range between about 100 nm and 600 nm.

30. The method of claim 27, wherein at least one of the one or more porous material layers has a porosity between about 60 and 90 percent and comprises porous silicon (Si) or porous silica (SiO₂).
